(19) United States
(12) Patent Application Publication
(10) Pub. No.: US 2019/0291040 A1
(43) Pub. Date: Sep. 26, 2019

(54) FILM FORMING APPARATUS AND GAS-LIQUID SEPARATING APPARATUS

(71) Applicants: Kabushiki Kaisha Toshiba, Tokyo (JP); Toshiba Electronic Devices & Storage Corporation, Tokyo (JP)

(72) Inventors: Rempei Nakata, Kanazawa Ishikawa (JP); Hidenori Hanyu, Kanazawa Ishikawa (JP)

(21) Appl. No.: 16/110,184

(22) Filed: Aug. 23, 2018

(30) Foreign Application Priority Data
Mar. 20, 2018 (JP) 2018-052022

(51) Int. Cl. B01D 47/02; C30B 25/14; C30B 29/06; C23C 16/44; C23C 16/24

(52) U.S. Cl. CPC B01D 47/024; C30B 25/14; C23C 16/24; C23C 16/4412; C30B 29/06

(57) ABSTRACT

A film forming apparatus according to an embodiment includes a reaction chamber; a first pipe having first end portion and second end portion, the first end portion being connected to the reaction chamber, the first pipe extending in a first direction, and having a first opening area in cross-section perpendicular to the first direction; a second pipe disposed such that the first pipe is provided between the reaction chamber and the second pipe, the second pipe having third end portion and fourth end portion, and the second pipe extending in a second direction different from the first direction; a narrow portion provided in the first pipe and having a second opening area smaller than the first opening area in cross-section perpendicular to the first direction; and a liquid storage portion located on an imaginary straight line extending from a center of the second end portion in the first direction.

### CROSS-REFERENCE TO RELATED APPLICATION

This application is based upon and claims the benefit of priority from Japanese Patent Application No. 2018-052022, filed on Mar. 20, 2018, the entire contents of which are incorporated herein by reference.

### FIELD

Embodiments described herein relate generally to a film forming apparatus and a gas-liquid separating apparatus.

### BACKGROUND

In a film forming apparatus for manufacturing a semiconductor device or a liquid crystal device, a film is formed on a substrate by using reactive gas. Generally, the film is formed by increasing a temperature of the substrate, flowing reactive gas such as raw material gas into a reaction chamber, and adjusting a flow rate or a pressure of the reactive gas. Exhaust gas containing the reactive gas not consumed in the reaction chamber or reaction by-product gas generated by the reaction is discharged from the reaction chamber to the outside of the film forming apparatus through an exhaust pipe, an exhaust pump, a detoxifying device, and the like.

The reaction by-products in the exhaust gas are cooled when the reaction by-products pass through the exhaust pipe from the reaction chamber, are condensed, and become droplets. However, the droplets cause clogging of the exhaust pipe or a failure of the exhaust pump. In addition, when the exhaust gas is detoxified by the detoxifying device, solid particles are produced as products and the exhaust pipe is clogged. If the exhaust pipe is clogged or the exhaust pump fails, maintenance work of the film forming apparatus is required and an operating ratio of the film forming apparatus is lowered.

### BRIEF DESCRIPTION OF THE DRAWINGS

FIG. 1 is a schematic diagram of an example of a film forming apparatus according to a first embodiment;

FIG. 2 is a partially enlarged view of the film forming apparatus according to the first embodiment;

FIG. 3 is a schematic diagram of a film forming apparatus according to a comparative example;

FIG. 4 is an explanatory diagram of functions and effects of the film forming apparatus according to the first embodiment;

FIG. 5 is a schematic diagram of an example of a film forming apparatus according to a second embodiment;

FIG. 6 is a schematic diagram of an example of a film forming apparatus according to a third embodiment;

FIG. 7 is a schematic diagram of an example of a film forming apparatus according to a fourth embodiment;

FIG. 8 is an explanatory view of a gas-liquid separating method using the film forming apparatus according to the fourth embodiment;

FIG. 9 is an explanatory view of a gas-liquid separating method using the film forming apparatus according to the fourth embodiment;

FIG. 10 is an explanatory view of a gas-liquid separating method using the film forming apparatus according to the fourth embodiment;

FIG. 11 is an explanatory view of a gas-liquid separating method using the film forming apparatus according to the fourth embodiment;

FIG. 12 is an explanatory view of a gas-liquid separating method using the film forming apparatus according to the fourth embodiment;

FIG. 13 is an explanatory view of a gas-liquid separating method using the film forming apparatus according to the fourth embodiment; and

FIG. 14 is an explanatory diagram of functions and effects of the film forming apparatus according to the fourth embodiment.

### DETAILED DESCRIPTION

Hereinafter, embodiments of the present disclosure will be described with reference to the drawings. In the following description, the same or similar members are denoted by the same reference numerals and the description of the members described once may be appropriately omitted.

### First Embodiment

A film forming apparatus according to a first embodiment includes: a reaction chamber; a first pipe having first end portion and second end portion, the first end portion being connected to the reaction chamber, the first pipe extending in a first direction in the vicinity of the second end portion, and having a first opening area in cross-section perpendicular to the first direction; a second pipe disposed such that the first pipe is provided between the reaction chamber and the second pipe, the second pipe having third end portion and fourth end portion, and the second pipe extending in a second direction different from the first direction in the vicinity of the third end portion; a narrow portion provided in the first pipe and having a second opening area smaller than the first opening area in cross-section perpendicular to the first direction; and a liquid storage portion located on an imaginary straight line extending from a center of the second end portion in the first direction.

A gas-liquid separating apparatus according to the first embodiment includes: a first pipe having first portion and second end portion, a mixture of gas and liquid being supplied to the first end portion, the first pipe extending in a first direction in the vicinity of the second end portion, and having a first opening area in cross-section perpendicular to the first direction; a second pipe connected to the first pipe, the second pipe having third end portion and fourth end portion, and the second pipe extending in a second direction different from the first direction in the vicinity of the third end portion; a narrow portion provided in the first pipe and having a second opening area smaller than the first opening area in cross-section perpendicular to the first direction; and a liquid storage portion located on an imaginary straight line extending from a center of the second end portion in the first direction.

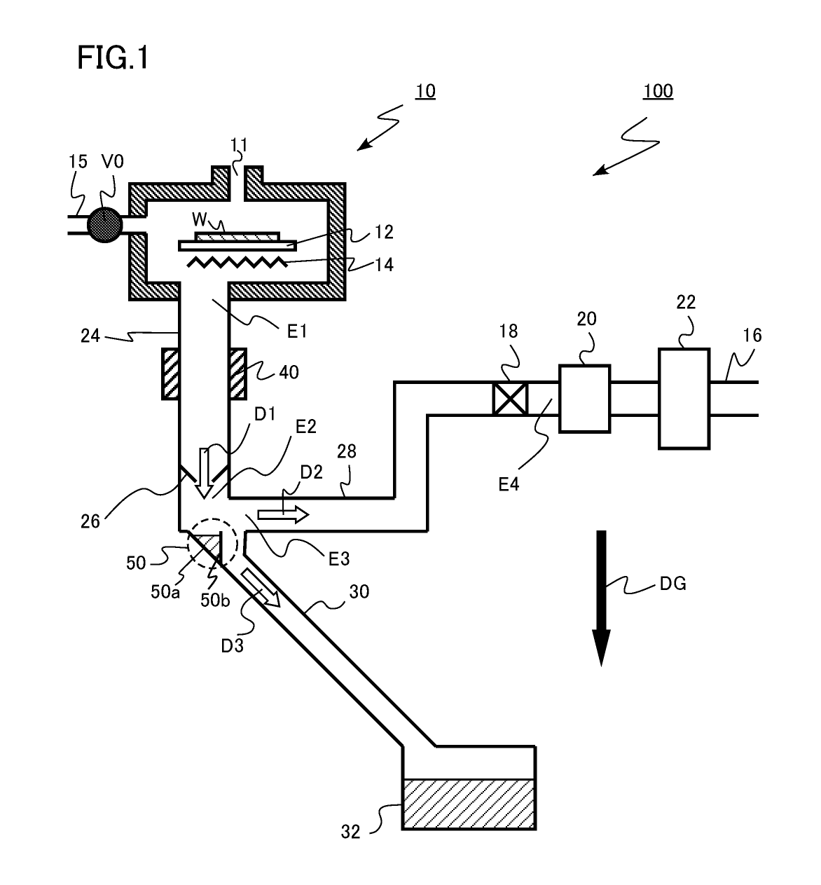

FIG. 1 is a schematic diagram of an example of a film forming apparatus according to a first embodiment. The film forming apparatus according to the example of the first embodiment is a film forming apparatus 100 for manufacturing a semiconductor device. The film forming apparatus 100 according to the first embodiment is a single-wafer type film forming apparatus 100 for an epitaxial film formation.

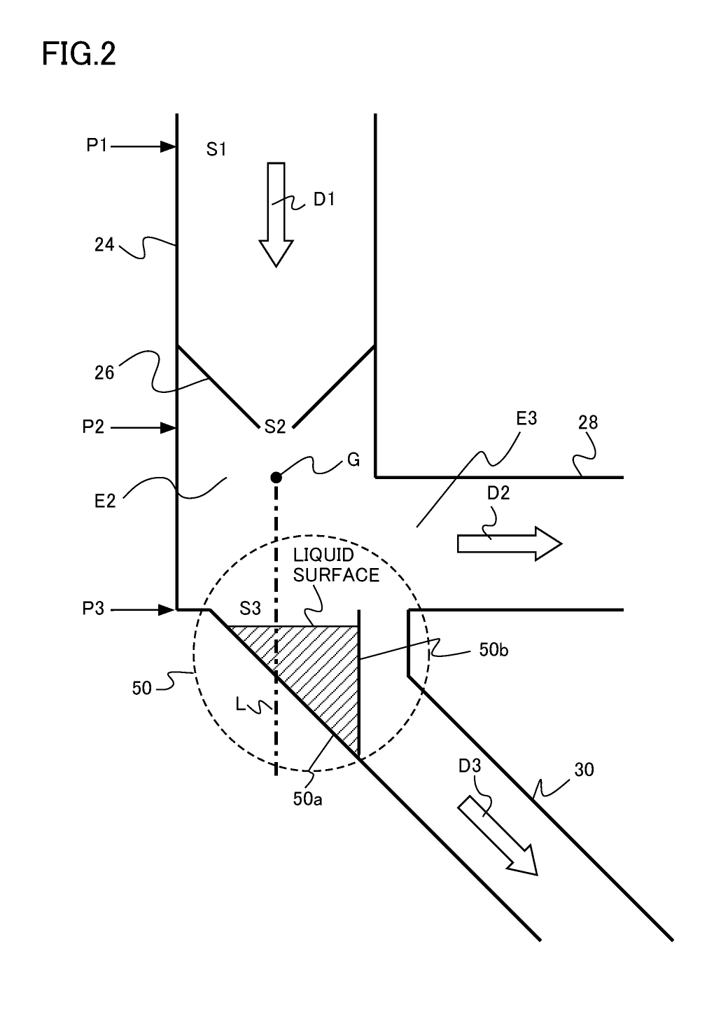

FIG. 2 is a partially enlarged view of the film forming apparatus 100 according to the first embodiment. FIG. 2 is an enlarged view of a region including a liquid storage portion 50 in FIG. 1.

The film forming apparatus 100 includes a reaction chamber 10, a gas supply port 11, a stage 12, a heater 14, a cleaning gas supply pipe 15, a discharge portion 16, a pressure adjustment valve 18, an exhaust pump 20 (pump), a detoxifying device 22, a first exhaust pipe 24 (first pipe), an orifice 26 (narrow portion), a second exhaust pipe 28 (second pipe), a drain 30 (third pipe), a drainage tank 32 (storage container), a cooling portion 40, and a liquid storage portion 50.

The reaction chamber 10 is provided with the stage 12 and the heater 14. A wafer W is disposed on the stage 12. The heater 14 heats the wafer W.

The gas supply port 11 is provided in an upper part of the reaction chamber 10. Raw material gas is supplied from the gas supply port 11 to the reaction chamber 10.

An inner portion of the reaction chamber 10 is depressurized to a desired pressure at the time of film formation. The exhaust gas containing the raw material gas not consumed in the reaction chamber 10 or reaction by-products generated by a reaction is discharged from the reaction chamber 10.

The cleaning gas supply pipe 15 is connected to the reaction chamber 10. The cleaning gas supply pipe 15 is provided with a valve V0. The cleaning gas supply pipe 15 supplies cleaning gas to the reaction chamber 10. By supplying the cleaning gas, the first exhaust pipe 24, the second exhaust pipe 28, the liquid storage portion 50, and the like are cleaned when film formation is not performed in the reaction chamber 10.

The first exhaust pipe 24 is provided between the reaction chamber 10 and the exhaust pump 20. The first exhaust pipe 24 is provided between the reaction chamber 10 and the drainage tank 32.

The first exhaust pipe 24 has a first end portion E1 and a second end portion E2. The first end portion E1 is connected to the reaction chamber 10.

The first exhaust pipe 24 extends in a first direction D1 in the vicinity of at least the second end portion E2. The first exhaust pipe 24 has a first opening area S1 in cross-section perpendicular to the first direction D1. For example, as shown in FIG. 2, the first exhaust pipe 24 has the first opening area S1 at a position P1 near the second end portion E2.

In the film forming apparatus 100, the first direction D1 is preferably matched with a direction of gravity (an arrow DG in FIG. 1). A movement direction of the exhaust gas in the first exhaust pipe 24 is matched with the first direction D1.

The exhaust gas discharged from the reaction chamber 10 passes through the first exhaust pipe 24. The exhaust gas contains the reaction by-products. A part of the reaction by-products in the exhaust gas is cooled and liquefied in the first exhaust pipe 24 and becomes droplets.

The cooling portion 40 is provided around the first exhaust pipe 24. The cooling portion 40 has a function of cooling an inner portion of the first exhaust pipe 24. The cooling portion 40 is, for example, a water cooling pipe.

The orifice 26 is an example of a narrow portion. The orifice 26 is provided in the first exhaust pipe 24. The orifice 26 has a second opening area S2 in a cross-section perpendicular to the first direction D1. As shown in FIG. 2, the orifice 26 has the second opening area S2 at a position P2.

The second opening area S2 is smaller than the first opening area S1. For example, the second opening area S2 is 2.5% to 20% of the first opening area S1.

Because the opening area of the first exhaust pipe 24 is reduced at a portion of the orifice 26, the exhaust gas discharged from the reaction chamber 10 is accelerated by the orifice 26. The accelerated exhaust gas is ejected in the first direction D1 from the orifice 26.

The first exhaust pipe 24 branches into the second exhaust pipe 28 and the drain 30.

The second exhaust pipe 28 is provided between the first exhaust pipe 24 and the exhaust pump 20. The first exhaust pipe 24 is provided between the reaction chamber 10 and the second exhaust pipe 28. The second exhaust pipe 28 has a third end portion P3 and a fourth end portion E4.

The second exhaust pipe 28 extends in a second direction D2 different from the first direction D1 in the vicinity of at least the third end portion E3. For example, an angle formed by the first direction D1 and the second direction D2 is 90 degrees. A fourth end portion P4 is connected to the exhaust pump 20.

The exhaust pump 20 is provided between the second exhaust pipe 28 and the discharge portion 16. The exhaust pump 20 has a function of depressurizing the inner portion of the reaction chamber 10. The exhaust pump 20 is, for example, a vacuum pump.

The pressure adjustment valve 18 is provided between the second exhaust pipe 28 and the exhaust pump 20. An inner portion of the reaction chamber 10 can be adjusted to a desired pressure by the pressure adjustment valve 18.

The detoxifying device 22 is provided between the exhaust pump 20 and the discharge portion 16. The detoxifying device 22 is, for example, a combustion type detoxifying device.

The detoxifying device 22 detoxifies the exhaust gas discharged from the reaction chamber 10. The detoxified exhaust, gas is discharged from the discharge portion 16 to the outside of the film forming apparatus 100.

The drain 30 is provided between the first exhaust pipe 24 and the drainage tank 32. The drain 30 extends in a third direction D3 different from the second direction D2. The third direction D3 is also different from the first direction D1. The drain 30 is connected to the drainage tank 32.

At least a part of the drain 30 is inclined with respect to the first direction D1. The drain 30 is horizontal or is inclined in the direction of gravity toward the drainage tank 32, in an entire region. In other words, the drain 30 is not inclined in a direction opposite to the direction of gravity toward the drainage tank 32.

The drainage tank 32 is an example of a storage container. The drainage tank 32 is located lower than the liquid storage portion 50 in the direction of gravity. The drainage tank 32 has a function of storing the discharged liquid originating from the reaction by-products.

In the drainage tank 32, liquid containing a part of the exhaust gas is stored. The liquid contains droplets originating from the discharged exhaust gas. By removing the liquid stored in the drainage tank 32, the liquid containing a part of the exhaust gas is discharged from the film forming apparatus 100.

The liquid storage portion 50 is located on an imaginary straight line (L in FIG. 2) that virtually extends in the first direction D1 from a center (G in FIG. 2) of the second end portion E2. In other words, the liquid storage portion 50 is located on an extension line of the first exhaust pipe 24. A center of the second end portion E2 is a geometric center of gravity of a cross-section of the second end portion E2 perpendicular to the first direction D1. For example, when the cross-section is circular, the center is a center of a circle. The liquid storage portion 50 is located on an imaginary straight line (L in FIG. 2) that virtually extends in the first direction D1 from a center of an opening portion of the orifice 26.

The liquid storage portion 50 is provided between the first exhaust pipe 24 and the second exhaust pipe 28. The liquid storage portion 50 is provided between the first exhaust pipe 24 and the drain 30. The liquid storage portion 50 is provided in a portion branching from the first exhaust pipe 24 to the second exhaust pipe 28 and the drain. 30.

The liquid storage portion 50 has an inclined surface 50a inclined with respect to the first direction D1 and a bank 50b provided on the inclined surface 50a. The bank 50b is, for example, a plate-like member connected to the inclined surface 50a. A recessed portion is formed by the inclined surface 50a and the bank 50b.

The liquid storage portion 50 has a function of capturing the droplets of the reaction by-products contained in the exhaust gas. The liquid storage portion 50 captures the droplets, stores the droplets as liquid, and forms a liquid surface. The droplets of the reaction by-products overflowing from the bank 50b of the liquid storage portion 50 pass through the drain 30 and are stored in the drainage tank 32.

The recessed portion formed by the inclined surface 50a and the bank 50b has a third opening area S3. As shown in FIG. 2, the recessed portion has the third opening area S3 at a position P3. The third opening area S3 is an opening area of the liquid storage portion 50 in cross-section perpendicular to the first direction D1. The third opening area S3 is larger than the second opening area S2, for example.

Hereinafter, a gas-liquid separating method using the film forming apparatus 100 according to the first embodiment will be described. The case where an epitaxial film of silicon is formed on the wafer W will be described as an example.

First, the wafer W is carried in the reaction chamber 10 and is disposed on the stage 12. Next, an inner portion of the reaction chamber 10 is depressurized using the exhaust pump 20 while hydrogen (H₂) is flown from the gas supply port 11. An internal pressure of the reaction chamber 10 is adjusted to a desired pressure by using the pressure adjustment valve 18. In addition, the wafer W is heated to, for example, 1000° C. by using the heater 14.

Next, raw material gas is supplied to the reaction chamber 10 from the gas supply port 11 and a silicon epitaxial film is formed on a surface of the wafer W. The raw material gas is, for example, dichlorosilane (SiH₂Cl₂), hydrogen (H₂), and hydrogen chloride (HCl).

Specifically, for example, when the silicon epitaxial film is formed, gas of chlorosilane polymers (SixHyClz: x is 2 or more) or chlorosilanes such as trichlorosilane tetrachlorosilane (SiCl₄), tetrachlorodisilane (SiHCl₃), hexachlorodisilane (Si₂Cl₆), and octachlorotrisilane (Si₃Cl₈) is generated as the reaction by-products. The chlorosilane polymers refer to molecular compounds having a main chain to which two or more silicon atoms are bonded and in which a substituent on the silicon atom is chlorine or hydrogen or substances in which a plurality of kinds of molecular compounds are mixed.

The reaction by-product gas and the raw material gas not used for film formation are contained in the gas discharged from the reaction chamber 10.

When a molecular weight of the reaction by-product gas or the raw material gas increases, a boiling point at the same pressure increases. For example, a normal boiling point of dichlorosilane as the raw material gas is about 8° C., whereas a normal boiling point of trichlorosilane is about 31° C. and a normal boiling point of tetrachlorosilane is about 57° C. A normal boiling point of chlorosilane polymers having a larger molecular weight further increases.

If the exhaust gas is discharged to the outside of the reaction chamber 10, the exhaust gas is cooled. First, gas of the chlorosilane polymers having high boiling points is condensed, is liquefied, and form droplets. If cooling of the exhaust gas is further performed, gas of chlorosilane polymers having low boiling points or gas of chlorosilanes is condensed, is liquefied, and form droplets. In addition, gas of some chlorosilane polymers may be solidified after sublimation or liquefaction and may become solid particles.

The exhaust gas discharged from the reaction chamber 10 is cooled by the cooling portion 40 in the first exhaust pipe 24 and the droplets are further grown.

The exhaust gas containing the droplets is accelerated by the orifice 26. The accelerated exhaust gas is ejected in the first direction D1 from the orifice 26.

The accelerated droplets collide with the inclined surface 50a of the liquid storage portion 50 and adhere to the inclined surface 50a. The droplets adhering to the inclined surface 50a are accumulated in the recessed portion formed by the inclined surface 50a and the bank 50b and form a liquid surface.

After the liquid surface is formed in the liquid storage portion 50, the accelerated droplets collide with the liquid surface and are integrated with the liquid. If a height of the liquid surface exceeds a height of the bank 50b, the liquid flows through the drain 30, flows to the drainage tank 32, and is stored.

The exhaust gas from which the droplets have been separated is detoxified by the detoxifying device 22 and is discharged from the discharge portion 16 to the outside of the film forming apparatus 100.

Next, functions and effects of the film forming apparatus 100 according to the first embodiment will be described.

In a general film forming apparatus, exhaust gas containing reaction by-product gas and raw material gas not used for film formation is discharged from the reaction chamber to the outside of the film forming apparatus through the exhaust pipe, the exhaust pump, the detoxifying device, and the like.

The reaction by-products in the exhaust gas are cooled when the reaction by-products pass through the exhaust pipe from the reaction chamber, are condensed, and become droplets. However, the droplets cause clogging of the exhaust pipe or a failure of the exhaust pump. In addition, when the exhaust gas is detoxified by the detoxifying device, solid particles are produced as products and the exhaust pipe is clogged.

If the exhaust pipe is clogged or the exhaust pump fails, maintenance work of the film forming apparatus is required and an operating ratio of the film forming apparatus is lowered. Also, the droplets originating from exhaust gas may contain harmful gas generating substances or ignitable substances and may be dangerous to the maintenance work. For this reason, it is desired to suppress clogging of the exhaust pipe or a failure of the exhaust pump due to the droplets originating from the exhaust gas.

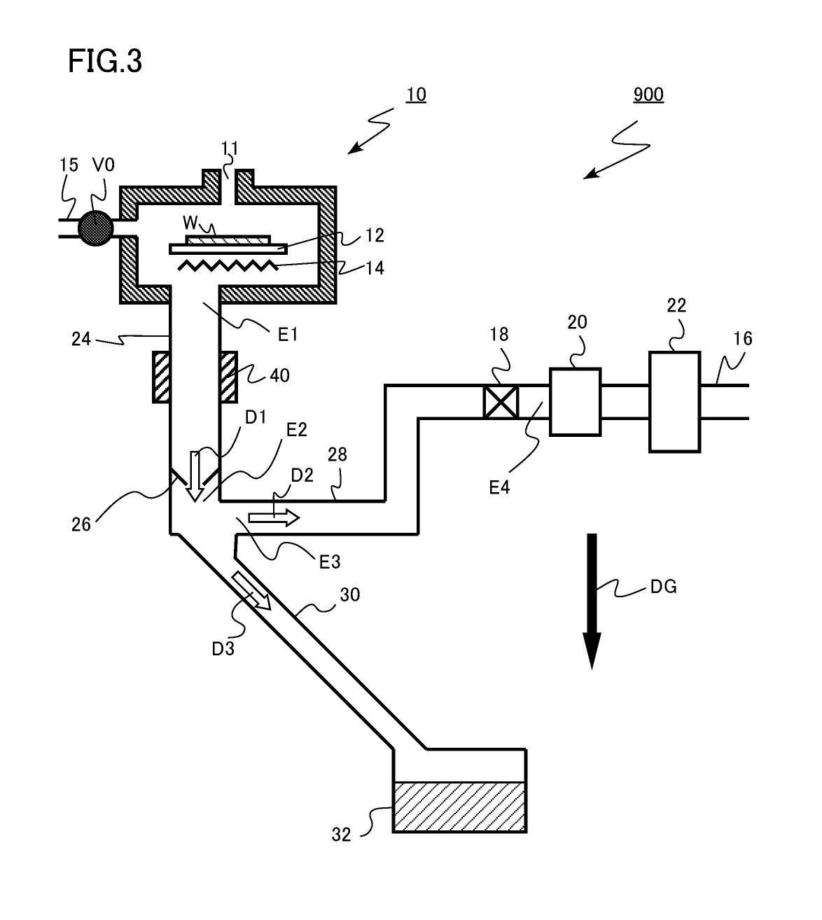

FIG. 3 is a schematic diagram of a film forming apparatus according to a comparative example. The film forming apparatus according to the comparative example is a film forming apparatus 900 for manufacturing a semiconductor device. The film forming apparatus 900 according to the comparative example is a film forming apparatus 900 for a sheet-type epitaxial film.

The film forming apparatus 900 according to the comparative example is different from the film forming apparatus 100 according to the first embodiment in that the liquid storage portion 50 is not provided.

The film forming apparatus 900 according to the comparative example causes the droplets of the reaction by-products injected and accelerated from the orifice 26 to collide with the inclined surface of the drain 30. As a result, it is possible to intensively capture the droplets and efficiently collect the droplets of the reaction by-products. The captured droplets flow to the drainage tank 32 along the drain 30 and are stored.

However, when a velocity of the droplets is high and kinetic energy of the droplets is large, the droplets bounce off the inclined surface of the drain 30, so that collection efficiency of the droplets may be lowered.

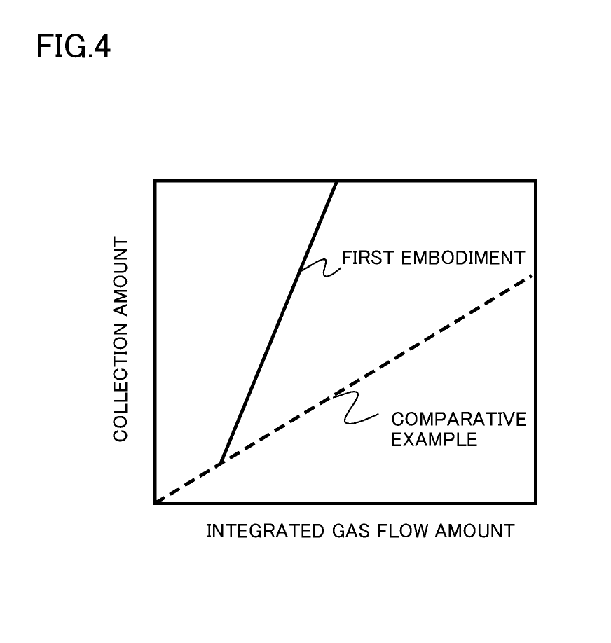

FIG. 4 is an explanatory diagram of functions and effects of the film forming apparatus according to the first embodiment. FIG. 4 shows a relation between an integrated supply amount of the raw material gas and a collection amount of the liquid stored in the drainage tank 32. As compared with the comparative example, in the case of the first embodiment, the collection amount increases after a certain time.

In the film forming apparatus 100 according to the first embodiment, the droplets of the reaction by-products in the exhaust gas ejected from the orifice 26 in the first direction D1 are captured by the liquid storage portion 50 existing right under the orifice 26. In the liquid storage portion, 50, the recessed portion is formed by the inclined surface 50a and the bank 50b. The droplets are accumulated in the concave portion formed by the inclined surface 50a and the bank 50b and a liquid pool having a liquid surface is formed.

It is considered that the droplets collide with the liquid surface, the droplets and the liquid are integrated, and bouncing of the droplets is suppressed. Therefore, it is considered that the collection efficiency of the droplets is improved. It is considered that the droplets are accumulated in the recessed portion and the collection efficiency of the droplets begins to increase from a time when the liquid surface is formed.

A density of the exhaust gas is preferably low from the viewpoint of integrating the droplets and the liquid and suppressing bouncing of the droplets. A wind pressure of the exhaust gas accelerated by the orifice 26 is proportional to the density and the velocity of the exhaust gas. It is considered that, if the density of the exhaust gas is lowered, an influence of the wind pressure is suppressed even when the velocity of the exhaust gas increases and integration of the droplets and the liquid is promoted.

The density of the exhaust gas can be lowered by reducing the pressure of the exhaust gas or reducing the mass of the exhaust gas. Therefore, the liquid storage portion 50 is depressurized to less than an atmospheric pressure. In addition, a main component of the exhaust gas is preferably hydrogen or helium having a small mass.

As described above, according to the first embodiment, the droplets collide with the liquid surface, the droplets and the liquid are integrated, and the collection efficiency of the droplets of the reaction by-products contained in the exhaust gas is improved. Therefore, it is possible to provide a film forming apparatus capable of suppressing clogging of an exhaust pipe or a failure of an exhaust pump.

### Second Embodiment

A film forming apparatus and a gas-liquid separating apparatus according to a second embodiment are different from the film forming apparatus and the gas-liquid separating apparatus according to the first embodiment in that a liquid storage portion has a cylindrical structure with a bottom surface. Hereinafter, description of contents overlapping with those of the first embodiment will be omitted.

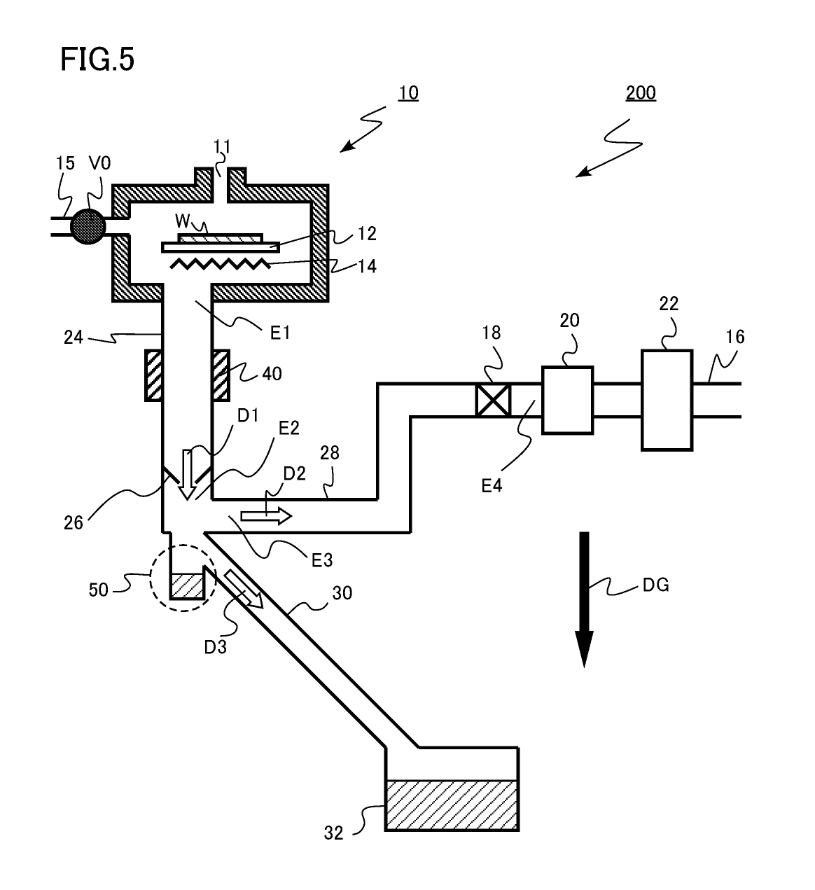

FIG. 5 is a schematic diagram of an example of the film forming apparatus according to the second embodiment. The film forming apparatus according to the example of the second embodiment is a film forming apparatus 200 for manufacturing a semiconductor device. The film forming apparatus 200 according to the second embodiment is a single-wafer type film forming apparatus 200 for an epitaxial film formation.

The film forming apparatus 200 includes a reaction chamber 10, a gas supply port 11, a stage 12, a heater 14, a cleaning gas supply pipe 15, a discharge portion 16, a pressure adjustment valve 18, an exhaust pump 20 (pump), a detoxifying device 22, a first exhaust pipe 24 (first pipe), an orifice 26 (narrow portion), a second exhaust pipe 28 (second pipe), a drain 30 (third pipe), a drainage tank 32 (storage container), a cooling portion 40, and a liquid storage portion 50.

The liquid storage portion 50 has a cylindrical structure with a bottom surface. The liquid storage portion 50 has a cylindrical recessed portion with a bottom surface.

The liquid storage portion 50 has a function of capturing droplets of reaction by-products contained in exhaust gas. The liquid storage portion 50 captures the droplets and stores the droplets as liquid. The liquid storage portion 50 stores the liquid and forms a liquid surface. The droplets of the reaction by-products overflowing from the liquid storage portion 50 pass through the drain 30 and are stored in the drainage tank 32.

According to the second embodiment, the droplets collide with the liquid surface, the droplets and the liquid are integrated, and collection efficiency of the droplets of the reaction by-products contained in the exhaust gas is improved, similarly to the first embodiment. Therefore, it is possible to provide a film forming apparatus capable of suppressing clogging of an exhaust pipe or a failure of an exhaust pump.

### Third Embodiment

A film forming apparatus and a gas-liquid separating apparatus according to a third embodiment are different from the film forming apparatus and the gas-liquid separating apparatus according to the second embodiment in that a drain 30 and a drainage tank 32 are not provided. Hereinafter, description of contents overlapping with those of the first and second embodiments will be omitted.

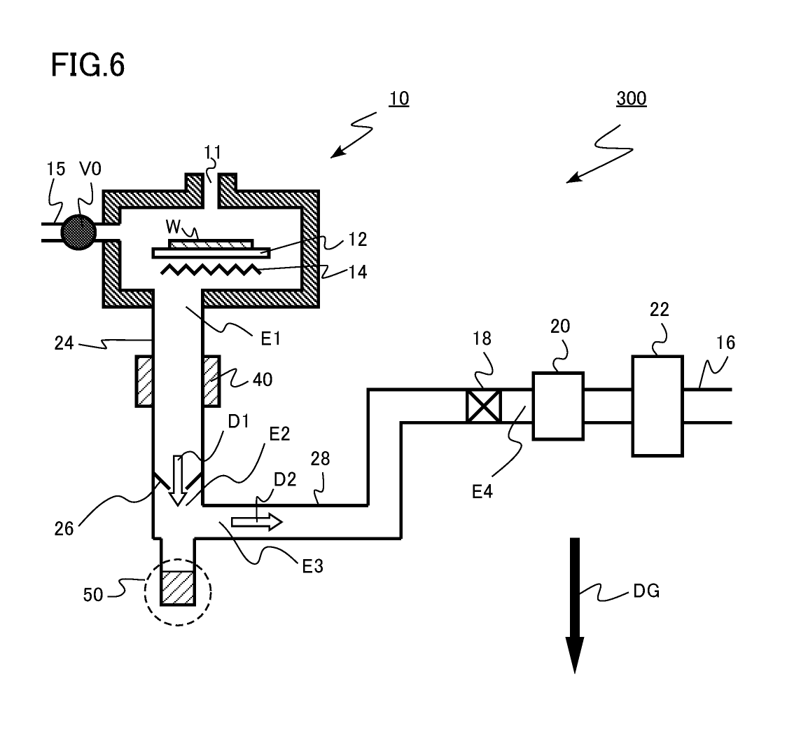

FIG. 6 is a schematic diagram of an example of the film forming apparatus according to the third embodiment. The film forming apparatus according to the example of the third embodiment is a film forming apparatus 300 for manufacturing a semiconductor device. The film forming apparatus 300 according to the third embodiment is a single-wafer type film forming apparatus 300 for an epitaxial film formation.

The film forming apparatus 300 includes a reaction chamber 10, a gas supply port 11, a stage 12, a heater 14, a cleaning gas supply pipe 15, a discharge portion 16, a pressure adjustment valve 18, an exhaust pump 20 (pump), a detoxifying device 22, a first exhaust pipe 24 (first pipe), an orifice 26 (narrow portion), a second exhaust pipe 28 (second pipe), a cooling portion 40, and a liquid storage portion 50.

The liquid storage portion 50 has a cylindrical structure with a bottom surface. The liquid storage portion 50 has a function of capturing droplets of reaction by-products contained in exhaust gas. The liquid storage portion 50 captures the droplets, stores the droplets as liquid, and forms a liquid surface.

For example, before the liquid storage portion 50 is filled with the liquid, the liquid storage portion 50 is removed and the liquid accumulated in the liquid storage portion 50 is removed.

According to the third embodiment, the droplets collide with the liquid surface, the droplets and the liquid are integrated, and collection efficiency of the droplets of the reaction by-products contained in the exhaust gas is improved, similarly to the first embodiment. Therefore, it is possible to provide a film forming apparatus capable of suppressing clogging of an exhaust pipe or a failure of an exhaust pump.

### Fourth Embodiment

A film forming apparatus and a gas-liquid separating apparatus according to a fourth embodiment are different from the film forming apparatuses and the gas-liquid separating apparatuses according to the first to third embodiments in that a bending structure to be convex in a direction of gravity is provided. Hereinafter, description of contents overlapping with those of the first to third embodiments will be omitted.

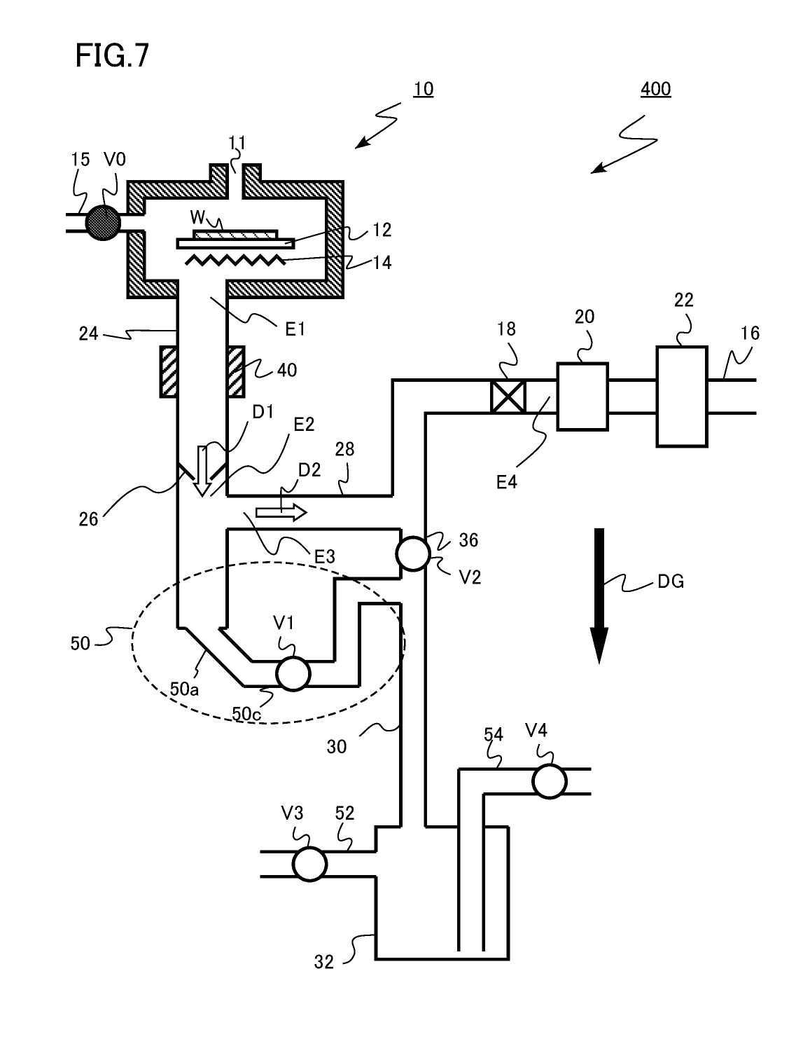

FIG. 7 is a schematic diagram of an example of the film forming apparatus according to the fourth embodiment. The film forming apparatus according to the example of the fourth embodiment is a film forming apparatus 400 for manufacturing a semiconductor device. The film forming apparatus 400 according to the fourth embodiment is a single-wafer type film forming apparatus 400 for an epitaxial film formation.

The film forming apparatus 400 includes a reaction chamber 10, a gas supply port 11, a stage 12, a heater 14, a cleaning gas supply pipe 15, a discharge portion 16, a pressure adjustment valve 18, an exhaust pump 20 (pump), a detoxifying device 22, a first exhaust pipe 24 (first pipe), an orifice 26 (narrow portion), a second exhaust pipe 28 (second pipe), a drain 30 (third pipe), a drainage tank 32 (storage container), a connection pipe 36 (fourth pipe), a cooling portion 40, a liquid storage portion 50, a pressure feed gas supply pipe 52, and a drainage pressure feed pipe 54.

The liquid storage portion 50 includes a U-shaped pipe 50c. The U-shaped pipe 50c is an example of a bending structure to be convex in a direction of gravity DG. The U-shaped pipe is disposed such that a convex region is oriented in the direction of gravity DG.

The cleaning gas supply pipe 15 has a valve V0. The U-shaped pipe 50c has a valve V1. The connection pipe 36 has a valve V2. The pressure feed gas supply pipe 52 has a valve V3. The drainage pressure feed pipe 54 has a valve V4.

Hereinafter, a gas-liquid separating method using the film forming apparatus 400 according to the fourth embodiment will be described. The case where an epitaxial film of silicon is formed on a wafer W will be described as an example. Hereinafter, description of contents overlapping with the gas-liquid separating method according to the first embodiment will be partially omitted.

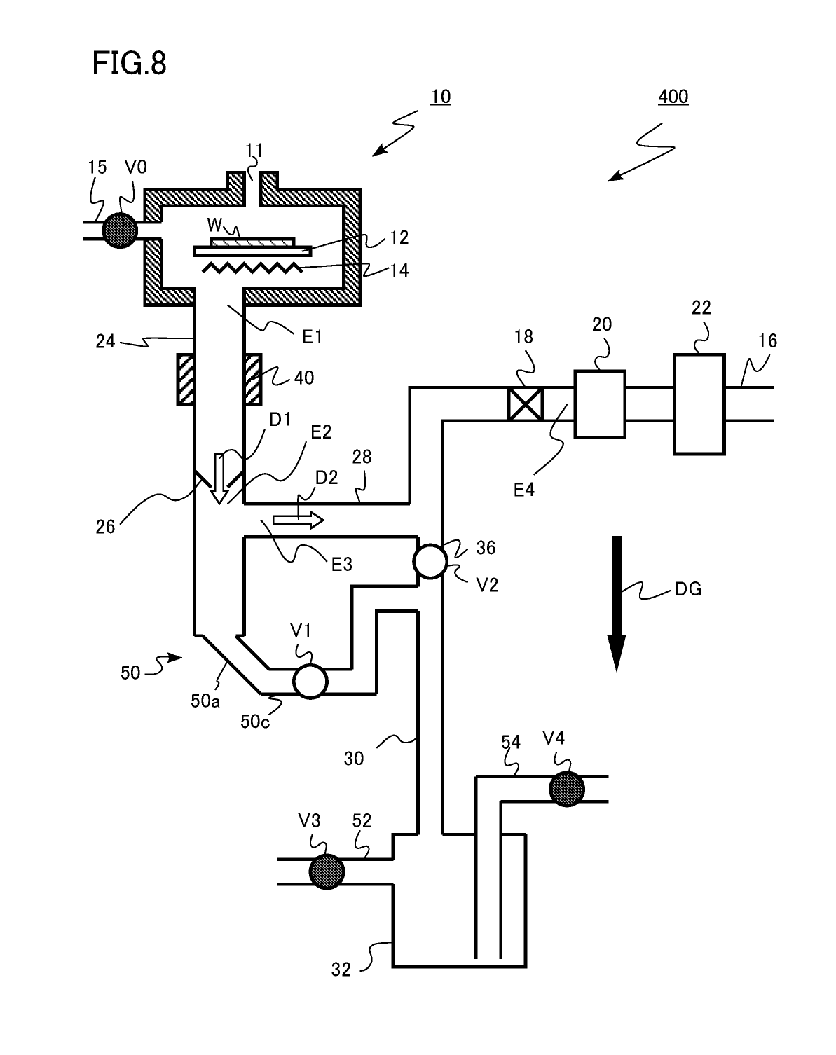

FIGS. 8 to 13 are explanatory views of a gas-liquid separating method using the film forming apparatus 400 according to the fourth embodiment; and In FIGS. 8 to 13, when the valves V0, V1, V2, V3, and V4 are white circles, the valves are opened and when the valves V0, V1, V2, V3, and V4 are black circles, the valves are closed.

First, the wafer W is carried in the reaction chamber 10 and is disposed on the stage 12. Next, an inner portion of the reaction chamber 10 is depressurized using the exhaust pump 20 while hydrogen (H₂) is flown from the gas supply port 11. An internal pressure of the reaction chamber 10 is adjusted to a desired pressure by using the pressure adjustment valve 18. The valves V3 and V4 are closed. The valves V1 and V2 are opened and the drainage tank 32 is also depressurized (FIG. 8).

Next, the wafer W is heated to, for example, 1000° C. by using the heater 14.

Next, raw material gas is supplied to the reaction chamber 10 from the gas supply port 11 and a silicon epitaxial film is formed on a surface of the wafer W. The raw material gas is, for example, dichlorosilane (SiH₂Cl₂, hydrogen (H₂), and hydrogen chloride (HCl).

Specifically, for example, when the silicon epitaxial film is formed, gas of chlorosilane polymers (SixHyClz: x is 2 or more) or chlorosilanes such as trichlorosilane (SiHCl₃), tetrachlorosilane (SiCl₄), tetrachlorodisilane (Si₂H₂Cl₄), hexachlorodisilane (Si₂Cl₆), and octachlorotrisilane (Si₃Cl₈) is generated as the reaction by-products.

The reaction by-product gas and the raw material gas not used for film formation are contained in the gas discharged from the reaction chamber 10.

If the exhaust gas is discharged to the outside of the reaction chamber 10, the exhaust gas is cooled. First, gas of the chlorosilane polymers having high boiling points is condensed, is liquefied, and form droplets. If cooling of the exhaust gas is further performed, gas of chlorosilane polymers having low boiling points or gas of chlorosilanes is condensed, is liquefied, and form droplets.

The exhaust gas discharged from the reaction chamber 10 is cooled by the cooling portion 40 in the first exhaust pipe 24 and the droplets are further grown.

The exhaust gas containing the droplets is accelerated by the orifice 26. The accelerated exhaust gas is ejected in the first direction D1 from the orifice 26.

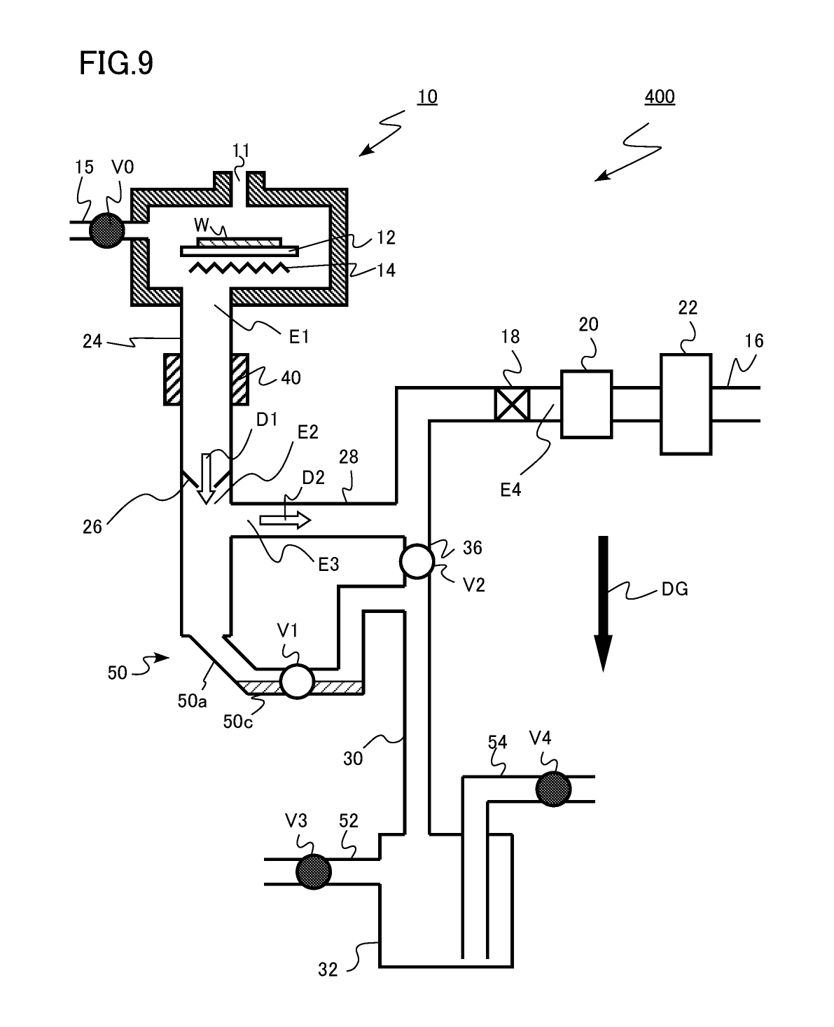

The accelerated droplets collide with the inclined surface 50a of the liquid storage portion 50 and adhere to the inclined surface 50a. The droplets adhering to the inclined surface 50a flow along the inclined surface 50a and begin to be accumulated at the bottom of the U-shaped pipe 50c. After a certain time, the liquid surface is formed (FIG. 9).

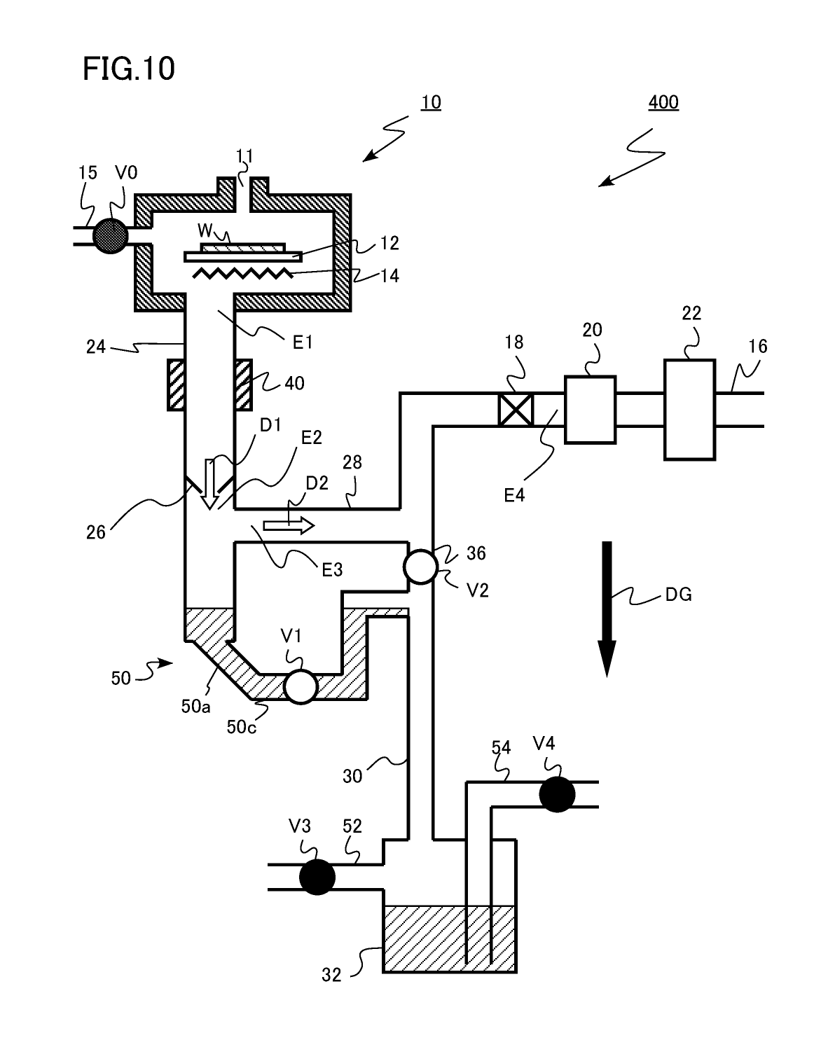

If the liquid is further accumulated, the liquid surface is also formed right under the orifice 26 (FIG. 10). If the liquid surface is formed right under the orifice 26, the accelerated droplets collide with the liquid surface, are integrated with the liquid, and are captured.

If a height of the liquid surface exceeds a bottom of a connection port between the U-shaped pipe 50c and the drain 30, the liquid flows through the drain 30, flows to the drainage tank 32, and is stored. Then, the height of the liquid surface right under the orifice 26 is constantly maintained.

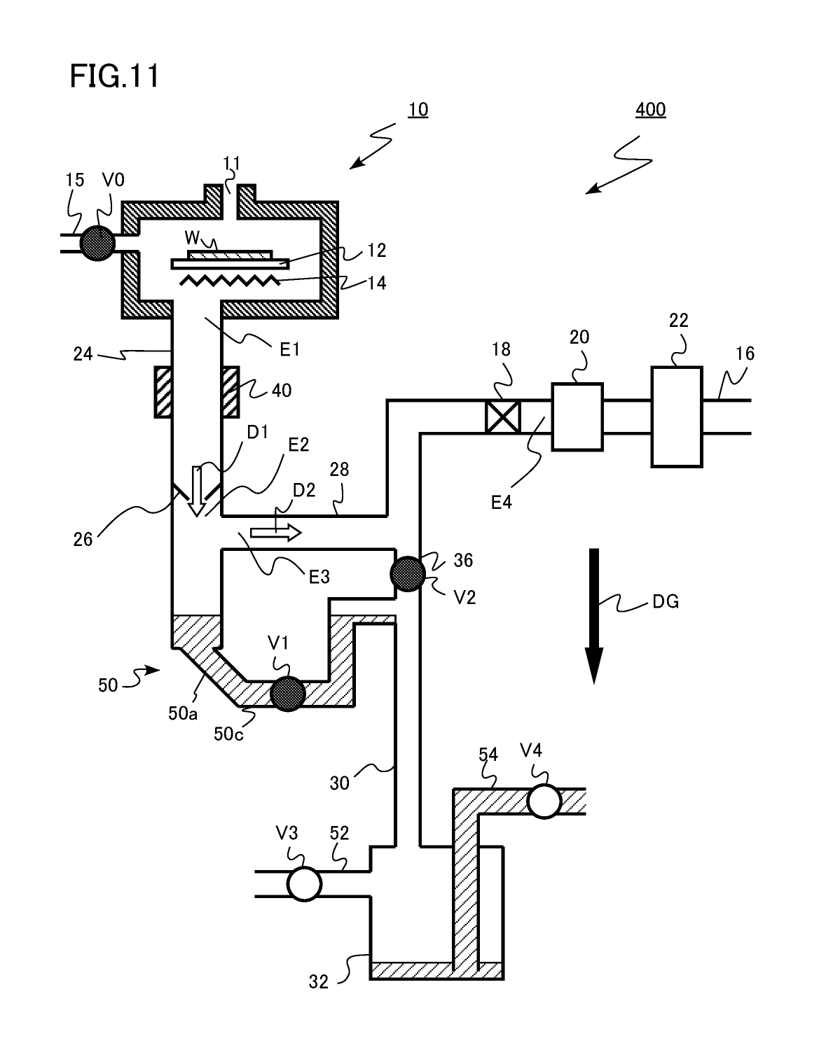

After formation of the silicon epitaxial film is completed, the valves V1 and V2 are closed. Then, the valves V3 and V4 are opened. The pressure feed gas is supplied from the pressure feed gas supply pipe 52 to the drainage tank 32 and the liquid accumulated in the drainage tank 32 is pressure-fed from the drainage pressure feed pipe 54 to the outside (FIG. 11). The pressure feed gas is, for example, nitrogen gas.

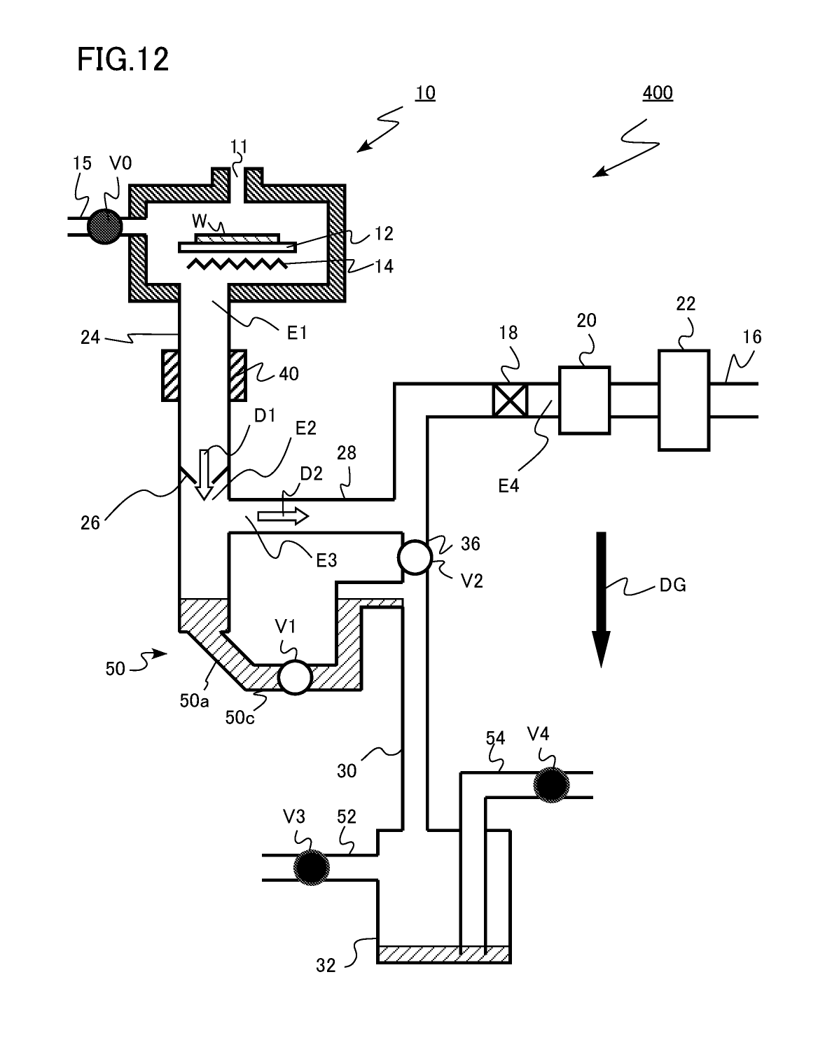

After pressure feeding of the liquid is completed, the valves V3 and V4 are closed. In addition, the valves V1 and V2 are opened and growth of a next silicon epitaxial film and separation and collection of the droplets from the exhaust gas are repeated (FIG. 12).

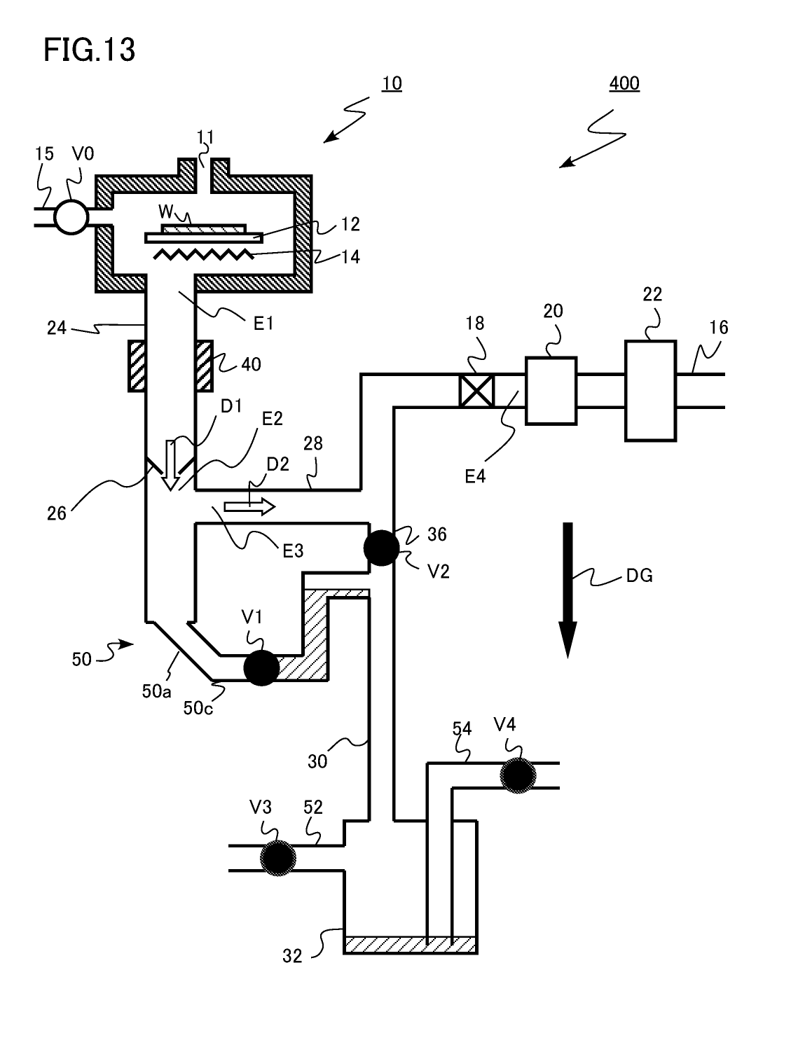

When the integrated flow rate of the raw material gas reaches a defined amount and cleaning of the reaction chamber 10, the first exhaust pipe 24, the second exhaust pipe 28, the liquid storage portion 50, and the like is performed, the valves V1 and V2 are closed. The valve V0 is opened (FIG. 13). In addition, the cleaning gas is supplied from the cleaning gas supply pipe 15 connected to the reaction chamber 10. The cleaning gas is, for example, chlorine trifluoride (ClF₃) gas.

By performing cleaning of the reaction chamber 10, the first exhaust pipe 24, the second exhaust pipe 28, the liquid storage portion 50, and the like, clogging of the exhaust pipe or a failure of the exhaust pump 20 is further suppressed. At the time of cleaning, the liquid accumulated on the side of the reaction chamber 10 rather than the valve V1 in the liquid storage portion 50 is also removed.

After cleaning is performed, the valves V1 and V2 are opened and growth of a next silicon epitaxial film and separation and collection of the droplets from the exhaust gas are performed. At that time, the liquid accumulated on the side of the drain 30 rather than the valve V1 in the liquid storage portion 50 passes through the valve V1 and is accumulated on the side of the reaction chamber 10.

Therefore, time until the liquid surface is formed right under the orifice 26 is shortened.

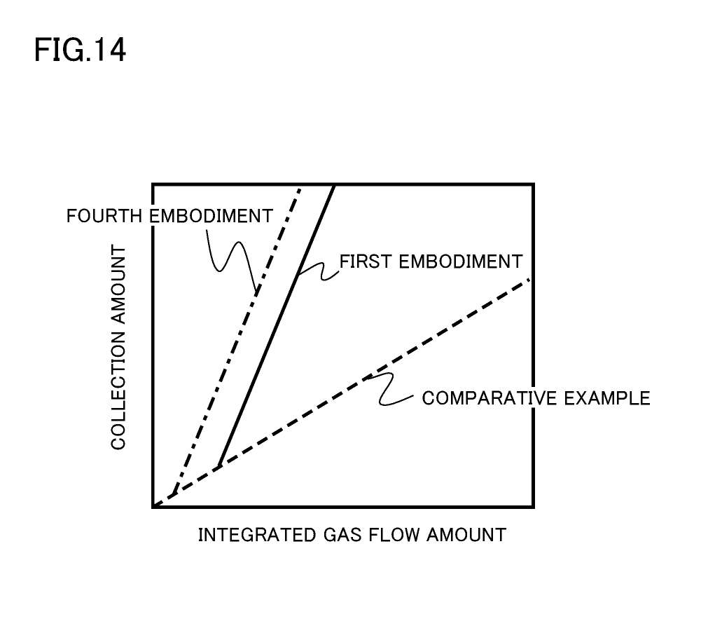

FIG. 14 is an explanatory diagram of functions and effects of the film forming apparatus according to the fourth embodiment. FIG. 14 shows a relation between the integrated supply amount of the raw material gas after cleaning and the collection amount of the liquid stored in the drainage tank 32. The cases of the first embodiment and the comparative example are also shown in FIG. 14.

In the case of the fourth embodiment, as compared with the first embodiment, the time until the collection amount starts to increase is shortened. This is because the time until the liquid surface is formed right under the orifice 26 is shortened.

In addition, in the case of the fourth embodiment, the collection amount of the liquid increases as compared with the first embodiment and the comparative example. Therefore, clogging of the exhaust pipe or a failure of the exhaust pump 20 is further suppressed.

In addition, in the fourth embodiment, an increased volume of the liquid by the liquid droplets captured on the liquid surface of the liquid storage portion 50 immediately exceeds a bottom of a connection port between the U-shaped pipe 50c and the drain 30 and the liquid flows to the drainage tank 32. Therefore, for example, it is possible to easily observe a change in the collection amount when film formation conditions such as a component ratio of the raw material gas and a wafer temperature are changed.

For example, in the case of the first embodiment, because the droplets collected on the liquid surface of the liquid storage portion 50 flow through the slope of the drain 30 and are stored in the drainage tank 32, a time lag occurs between capturing of the droplets in the liquid storage portion 50 and storing of the droplets in the drainage tank 32.

In the fourth embodiment, for example, the bending structure to be convex in the direction of gravity DG may be formed by a pipe structure other than the U-shaped pipe 50c.

In the first to fourth embodiments, the orifice 26 has been described as an example of the narrowed portion. However, the narrow portion is not limited to the orifice 26 as long as the narrow portion has a structure in which an opening area decreases. For example, the narrow portion may be a pipe in which an opening area is small.

In the first to fourth embodiments, the film forming apparatus for manufacturing a semiconductor device has been described as an example of a film forming apparatus. However, the present disclosure can also be applied to a film forming apparatus for manufacturing a liquid crystal device, for example.

In addition, in the first to fourth embodiments, the case where the gas-liquid separating apparatus is applied to the film forming apparatus has been described as an example. However, the gas-liquid separating apparatus according to each of the first to fourth embodiments can be widely used for separating liquid from a mixture of the gas and the liquid. For example, the gas-liquid separating apparatus can be widely used for separating droplets from the gas containing the droplets. For example, the gas-liquid separating apparatus can be applied to separation of droplets of oil contained in exhaust gas of a compressor. For example, the gas-liquid separating apparatus can be applied to separation of droplets of oil contained in exhaust gas from an engine of a vehicle or the like. For example, the gas-liquid separating apparatus can be applied to separation of water contained in exhaust gas of a fuel cell. For example, the gas-liquid separating apparatus can be applied to separation of water contained in exhaust gas of an air cleaner.

While certain embodiments have been described, these embodiments have been presented by way of example only, and are not intended to limit the scope of the inventions. Indeed, the film forming apparatus and the gas-liquid separating apparatus described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A film forming apparatus comprising:
a reaction chamber;
a first pipe having first end portion and second end portion, the first end portion being connected to the reaction chamber, the first pipe extending in a first direction in the vicinity of the second end portion, and having a first opening area in cross-section perpendicular to the first direction;
a second pipe disposed such that the first pipe is provided between the reaction chamber and the second pipe, the second pipe having third end portion and fourth end portion, the third end portion being on an end closer to the first pipe than the fourth end portion, and the second pipe extending in a second direction different from the first direction in the vicinity of the third end portion;
a narrow portion provided in the first pipe and having a second opening area smaller than the first opening area in cross-section perpendicular to the first direction; and
a liquid storage portion located on an imaginary straight line extending from a center of the second end portion in the first direction.

2. The film forming apparatus according to claim 1, further comprising: a pump disposed such that the first pipe and the second pipe are provided between the reaction chamber and the pump, and the pump depressurizing an inner portion of the reaction chamber.

3. The film forming apparatus according to claim 1, wherein the liquid storage portion is provided between the first pipe and the second pipe.

4. The film forming apparatus according to claim 1, wherein the liquid storage portion includes a recessed portion.

5. The film forming apparatus according to claim wherein a third opening area of the recessed portion in cross-section perpendicular to the first direction is larger than the second opening area.

6. The film forming apparatus according to claim 1, wherein the liquid storage portion includes an inclined surface inclined with respect to the first direction and a bank provided on the inclined surface.

7. The film forming apparatus according to claim 1, further comprising: a storage container located lower than the liquid storage portion in a direction of gravity.

8. The film forming apparatus according to claim 7, further comprising: a third pipe provided between the liquid storage portion and the storage container.

9. The film forming apparatus according to claim 8, wherein the third pipe is inclined in the direction of gravity toward the storage container, in an entire region.

10. The film forming apparatus according to claim 8, wherein the liquid storage portion includes a bending structure to be convex in the direction of gravity.

11. The film forming apparatus according to claim 10, further comprising: a fourth pipe connecting the second pipe and the third pipe.

12. A gas-liquid separating apparatus comprising:
a first pipe having first end portion and second end portion, a mixture of gas and liquid being supplied to the first end portion, the first pipe extending in a first direction in the vicinity of the second end portion, and having a first opening area in cross-section perpendicular to the first direction;
a second pipe connected to the first pipe, the second pipe having third end portion and fourth end portion, the third end portion being on an end closer to the first pipe than the fourth end portion, and the second pipe extending in a second direction different from the first direction in the vicinity of the third end portion;
a narrow portion provided in the first pipe and having a second opening area smaller than the first opening area in cross-section perpendicular to the first direction; and
a liquid storage portion located on an imaginary straight line extending from a center of the second end portion in the first direction.

13. The gas-liquid separating apparatus according to claim 12, further comprising: a pump disposed such that the second pipe is provided between the first pipe and the pump, and the pump depressurizing the first pipe, the second pipe, and the liquid storage portion.

14. The gas-liquid separating apparatus according to claim 12, wherein the liquid storage portion is provided between the first pipe and the second pipe.

15. The gas-liquid separating apparatus according to claim 12, wherein the liquid storage portion includes a recessed portion.
